(19) United States
(12) Patent Application Publication
(10) Pub. No.: US 2025/0299921 A1
(43) Pub. Date: Sep. 25, 2025

(54) IMPEDANCE TUNING FOR PLASMA PROCESSING

(71) Applicant: Applied Materials, Inc., Santa Clara, CA (US)

(72) Inventors: Yue GUO, Redwood City, CA (US); Nicolas J. BRIGHT, Arlington, WA (US); Kartik RAMASWAMY, San Jose, CA (US); Yang YANG, San Diego, CA (US); A N M Wasekul AZAD, Santa Clara, CA (US)

(21) Appl. No.: 18/612,601

(22) Filed: Mar. 21, 2024

(51) Int. Cl. H01J 37/32

(52) U.S. Cl. CPC H01J 37/32183; H01J 37/32128; H01J 37/32165; H01J 2237/327

(57) ABSTRACT

Embodiments of the disclosure include apparatus (e.g., plasma processing systems) and methods for plasma processing. A real component of a first impedance of a first radio frequency (RF) waveform is matched using a first capacitor of a tuning circuit. A real component of a second impedance of a second RF waveform is matched using a second capacitor of the tuning circuit. An imaginary component of the first impedance is matched using a third capacitor of the tuning circuit. An imaginary component of the second impedance is matched using the third capacitor of the tuning circuit.

### BACKGROUND

### Field

Embodiments described herein generally relate to a system and methods used in semiconductor device fabrication. More specifically, embodiments of the present disclosure relate to impedance tuning for plasma processing.

### Description of the Related Art

In plasma processing systems, a plasma is typically generated and maintained using a radio frequency (RF) power source which supplies RF power to the plasma and has a corresponding impedance. The plasma also has a corresponding impedance, and matching the impedance of the RF power source with the impedance of the plasma is important for efficiently maintaining the plasma and for preventing damage to the RF power source. For example, if the impedance of the RF power source and the impedance of the plasma are mismatched, then RF power supplied by the RF power source can reflect back rather than being transferred to the plasma. In certain scenarios, this reflected power can damage the RF power source. Even in scenarios in which the impedance mismatches do not cause damage to the RF power source, the mismatches are still undesirable because they decrease the efficiency of power transfer from the RF power source to the plasma.

However, matching the impedance of the RF power source with the impedance of the plasma is challenging because the impedance of the plasma is dynamic and changes rapidly. For instance, the rapid changes in the impedance of the plasma occur due to a variety of factors such as inputs from another system controlling the plasma (e.g., a pulsed DC voltage source), frequency shifts, non-uniform plasma distributions, etc. Due to limitations of matching components (e.g., time constants), the impedance of the plasma can change faster than it can be matched. For example, the impedance of the plasma changes from a first value to a second value before the impedance of the RF power source can match the first value.

Accordingly, there is a need in the art for a desirable impedance matching technique that solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the present disclosure provide a method for plasma processing. The method generally includes matching a real component of a first impedance of a first radio frequency (RF) waveform using a first capacitor of a tuning circuit. A real component of a second impedance of a second RF waveform is matched using a second capacitor of the tuning circuit. An imaginary component of the first impedance is matched using a third capacitor of the tuning circuit. An imaginary component of the second impedance is matched using the third capacitor of the tuning circuit.

Embodiments of the present disclosure provide a tuning circuit including a first capacitor, a second capacitor, and a third capacitor. The first capacitor is coupled to an output of the tuning circuit and configured to match a real component of a first impedance of a first radio frequency (RF) waveform provided to a first input of the tuning circuit. The second capacitor is coupled to the output of the tuning circuit and configured to match a real component of a second impedance of a second RF waveform provided to a second input of the tuning circuit. The third capacitor is coupled to the output of the tuning circuit and configured to match an imaginary component of the first impedance and match an imaginary component of the second impedance.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic representation of an example plasma processing system, in accordance with certain embodiments of the present disclosure.

FIG. 1B is a schematic representation of an example radio frequency (RF) match system, in accordance with certain embodiments of the present disclosure.

FIG. 1C is a schematic representation of an example tuning circuit, in accordance with certain embodiments of the present disclosure.

FIG. 1D illustrates a graph of a voltage waveform that is established on a substrate due to a voltage waveform applied to an electrode within a processing chamber, in accordance with certain embodiments of the present disclosure.

FIG. 2 illustrates a graph of two example impedance states, in accordance with certain embodiments of the present disclosure.

FIG. 3 illustrates a representation of example radio frequency (RF) multilevel pulsing, in accordance with certain embodiments of the present disclosure.

FIG. 4 is a flow diagram illustrating a method of impedance tuning for plasma processing, in accordance with certain embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to apparatus and methods for impedance matching. More specifically, embodiments described herein provide impedance tuning for plasma processing. In some embodiments, a source radio frequency (RF) generator outputs a first RF waveform and a second RF waveform. In other embodiments, a first source RF generator outputs the first RF waveform and a second source RF generator outputs the second RF waveform.

In one or more embodiments, the first RF waveform has a first impedance and the second RF waveform has a second impedance, and the first and second RF waveforms supply RF power to a plasma that has a load impedance. The load impedance is dynamic and can change significantly within relatively short amounts of time (e.g., microseconds). In various embodiments, the RF power is supplied to the plasma by either the first RF waveform or the second RF waveform. In some embodiments, in order to match the first impedance and the second impedance with the load impedance that changes rapidly (and is different relative to the first RF waveform and relative to the second RF waveform), a tuning circuit includes a first variable capacitor, a second variable capacitor, and a third variable capacitor.

In certain embodiments, the first variable capacitor of the tuning circuit is configured to match a real component of the first impedance with a real component (e.g., a first real component) of the load impedance of the plasma. In some examples, the second variable capacitor of the tuning circuit is configured to match a real component of the second impedance with the real component (e.g., a second real component) of the load impedance. In one or more embodiments, the third variable capacitor is configured to match an imaginary component of the first impedance with an imaginary component (e.g., a first imaginary component) of the load impedance of the plasma. In some embodiments, the third variable capacitor is configured to match an imaginary component of the second impedance with the imaginary component (e.g., a second imaginary component) of the load impedance.

By matching multiple impedances (e.g., the first impedance and the second impedance) with the load impedance of the plasma, the tuning circuit is capable of matching changes in the load impedance in a relatively short amount of time (e.g., about a microsecond). Matching the load impedance as quickly as it changes increases the efficiency of power delivery to the plasma and reduces power reflection. This is not possible in conventional systems which are not capable of matching the load impedance as rapidly as the load impedance changes.

### Processing System Examples

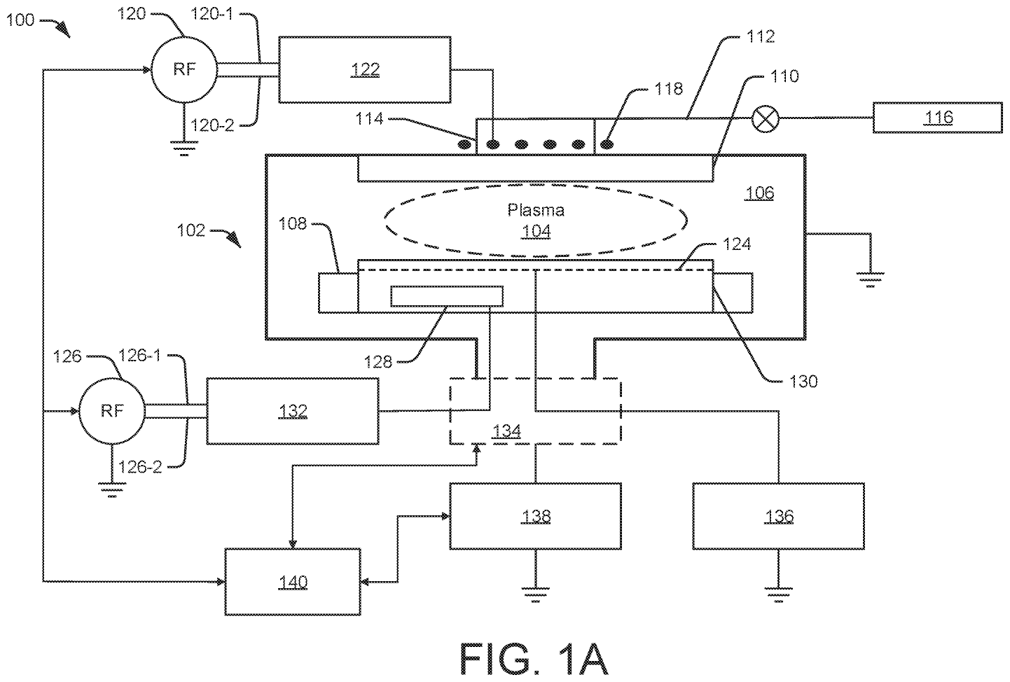

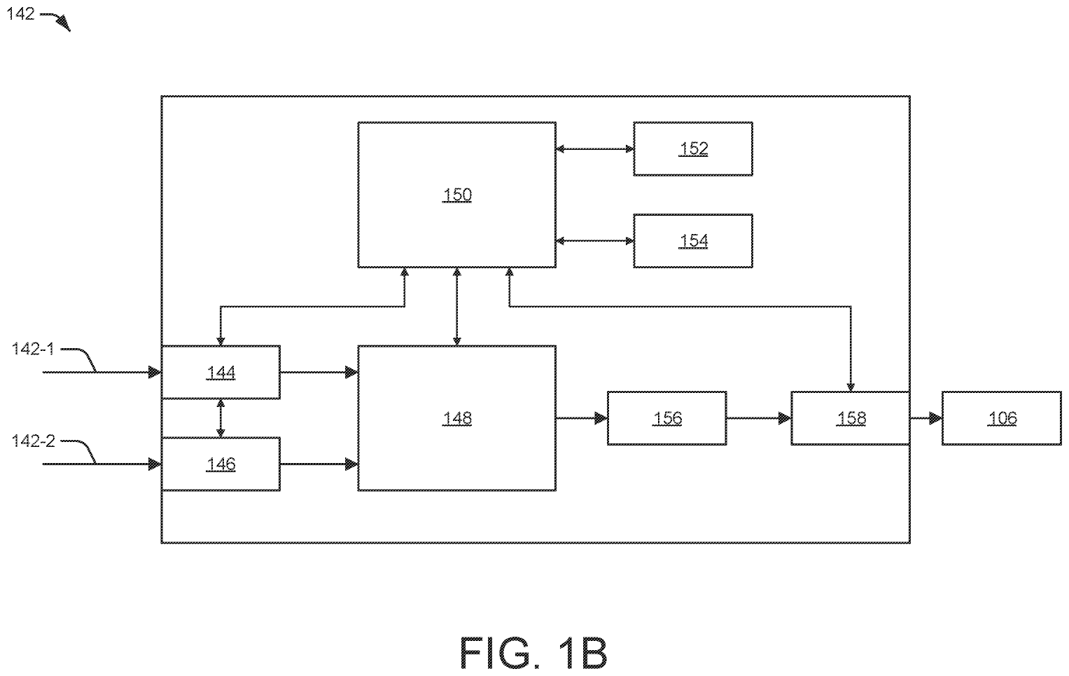

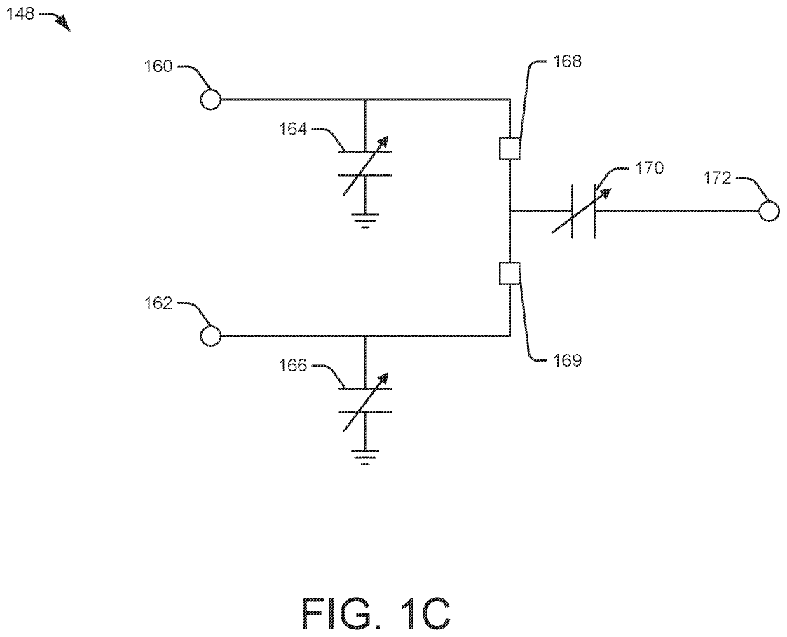

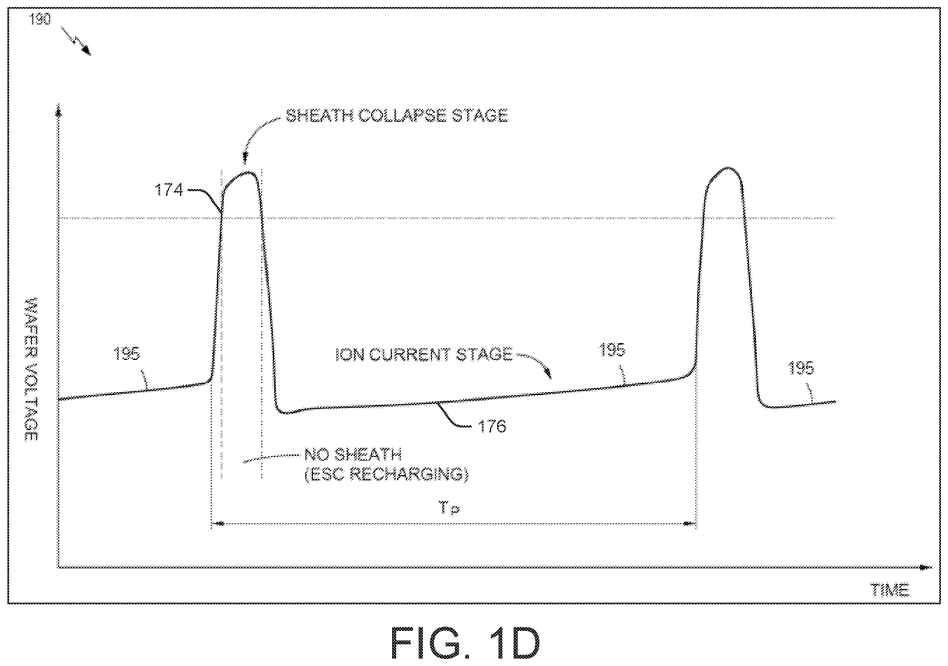

FIG. 1A is a schematic representation of an example plasma processing system 100. In some embodiments, the plasma processing system 100 is configured for plasma-assisted etching processes, such as a reactive ion etch (RIE) plasma processing. The plasma processing system 100 can also be used in other processes such as plasma-enhanced chemical vapor deposition (PECVD) processes, plasma-enhanced physical vapor deposition (PEPVD) processes, plasma-enhanced atomic layer deposition (PEALD) processes, plasma treatment processing, plasma-based ion implant processing, or plasma doping processing. In some embodiments, as shown in FIG. 1A, the plasma processing system 100 is configured to generate a plasma using an inductively coupled plasma (ICP) source disposed over a processing region of the plasma processing system 100 in which an RF signal is provided to a coil (e.g., coil 118 in FIG. 1A) within the plasma processing system 100. In other embodiments, a plasma may alternately be generated by a capacitively-coupled-plasma (CCP) system in which an RF signal is provided to an electrode (e.g., showerhead) within the plasma processing system 100.

The plasma processing system 100 includes a plasma processing chamber 102 which is illustrated to include a plasma 104 in a processing region 106 of the plasma processing chamber 102. The plasma 104 is disposed between a substrate support assembly 108 and a chamber lid 110 of the plasma processing chamber 102. The chamber lid 110 can include one or more sidewalls and a chamber base that are configured to withstand forces/pressures while the plasma 104 is generated within a vacuum environment maintained in the processing region 106 of the plasma processing chamber 102. In some CCP embodiments, the chamber lid 110 can be a conductive plate that is grounded to function as an upper electrode of the plasma processing system 100.

A gas delivery system 112 includes one or more gas inlets 114, and the gas delivery system 112 is coupled to the processing region 106 of the plasma processing chamber 102. The gas delivery system 112 is configured to deliver at least one processing gas (e.g., argon, nitrogen, oxygen, hydrogen, etc.) from at least one gas processing source 116 to the processing region 106 via the gas inlets 114 which extend through the chamber lid 110. Depending on the plasma process, the processing gas can include at least one of an inert gas (e.g., helium, argon, nitrogen (N₂)) or dry etching gas (e.g., HBr, HF, HCl, CF₄, NF₃ or XeF₂). In some embodiments, the gas delivery system 112 can include components for activating or energizing one or more processing gasses before delivering the processing gasses to the processing region 106.

The plasma processing system 100 includes a radio frequency (RF) coil 118 configured to induce an oscillating electromagnetic field (e.g., a time varying magnetic field and a corresponding electric field) within the plasma processing chamber 102. Interactions of with the electric field induced by the RF coil 118 cause ionization of atoms/molecules of one or more gasses delivered to the processing region 106 by the gas delivery system 112. Ionizing the gas atoms/molecules forms a plasma state that is usable to initiate and/or maintain the plasma 104.

In order to induce the electromagnetic field within the plasma processing chamber 102, a source RF generator 120 delivers RF power to the processing region 106 of the plasma processing chamber 102. In some embodiments, the source RF generator 120 includes a first output 120-1 configured to deliver a first RF waveform to the processing region 106 and a second output 120-2 configured to deliver a second RF waveform to the processing region 106. In other embodiments, the source RF generator 120 includes a first generator having the first output 120-1 configured to deliver the first RF waveform to the processing region 106 and a second generator having the second output 120-2 configured to deliver the second RF waveform to the processing region 106. In various embodiments, the first RF waveform has a first power level, a first frequency, and a first impedance. In one or more embodiments, the second RF waveform has a second power level, a second frequency, and a second impedance. In certain embodiments, the first impedance includes a first real component and a first imaginary component, and the second impedance includes a second real component and a second imaginary component.

In some embodiments, the first output 120-1 and the second output 120-2 are electrically coupled to the RF coil 118 such that RF power generated by the source RF generator 120 can be delivered to the RF coil 118. A center frequency of power delivered by the first output 120-1 and/or the second output 120-2 may be from 13.56 MHz to the very high frequency band such as 40 MHz, 60 MHz, 120 MHZ, or 162 MHz. The delivered power from the first output 120-1 and/or the second output 120-2 can be operated in a continuous mode or a pulsed mode. A pulsing frequency of the delivered power from the first output 120-1 and/or the second output 120-2 can be from 100 Hz to 10 KHz with duty cycles ranging from 5 percent to 95 percent. The source RF generator 120 has a frequency tuning capability and can adjust its delivered power frequency from the first output 120-1 and/or the second output 120-2 within e.g., ±5 percent or ±10 percent. In some embodiments, the source RF generator 120 switches the delivered power frequency from the first output 120-1 and/or the second output 120-2 at a predefined speed (e.g., two nanoseconds, fifty nanoseconds, etc.).

The source RF generator 120 delivers RF alternating current from the first output 120-1 and the second output 120-2 to the RF coil 118 which flows through the RF coil 118 and generates a time varying magnetic field. For instance, the time varying magnetic field induces an electric field which interacts with charged particles within one or more gasses delivered to the processing region 106 by the gas delivery system 112 causing the charged particles to gain energy. Some electrons gain enough energy to break free of atomic orbits which generates free electrons. These energized free electrons collide with neutral gas atoms/molecules causing the atoms/molecules to ionize by gaining/losing electrons. As a result, the plasma 104 forms as a mixture of free electrons, positive ions, and neutral atoms/molecules.

Once formed, the plasma 104 has a corresponding impedance which changes rapidly and unpredictably in some examples. The changing impedance of the plasma 104 is significant because power transfer from a source (e.g., the first output 120-1 and the second output 120-2) to a load (e.g., the plasma 104) is maximized when an impedance of the source matches an impedance of the load. Accordingly, in order to maximize power transfer from the first output 120-1 to the plasma 104, the first impedance of the first RF waveform should be tuned to match the impedances of the plasma 104. Similarly, in order to maximize power transfer from the second output 120-2 to the plasma 104, the second impedance of the second RF waveform should also be tuned match the impedances of the plasma 104.

In some embodiments, in order to tune the first and second impedances of the first and second RF waveforms to match the impedances of the plasma 104, an RF match system 122 is disposed between the source RF generator 120 (e.g., the first output 120-1 and the second output 120-2) and the RF coil 118. The RF match system 122 is an electrical circuit disposed between the first and second outputs 120-1, 120-2 and a plasma reactor (e.g., the processing region 106 of the plasma processing chamber 102) for optimizing efficiency of power delivery to the plasma 104. In certain embodiments, the RF match system 122 is configured to match the first and second impedances of the first and second RF waveforms with the impedances of the plasma 104 as described in greater detail with respect to FIGS. 1B and 1C.

The plasma processing system 100 is illustrated to include a chucking electrode 124 (e.g., an electrostatic chuck) disposed in the substrate support assembly 108. The chucking electrode 124 is configured to immobilize and stabilize substrates/wafers during plasma processing using an electrostatic force between the chucking electrode 124 and the substrates/wafers. The electrostatic force is generated by applying a voltage to the chucking electrode 124 during the plasma processing. After the plasma processing, the substrates/wafers are released by halting the application of the voltage to the chucking electrode 124.

In one or more embodiments, the plasma processing system 100 includes a bias RF generator 126 configured to deliver RF power to an electrode 128 of a substrate support 130 disposed in the processing region 106 of the plasma processing chamber 102. In various examples, the bias RF generator 126 delivers the RF power to the electrode 128 in order to control energy of ions reaching a surface of the substrates/wafers, enhance directionality of ion bombardment, control a voltage applied to the substrates/wafers, etc. In some embodiments, the bias RF generator 126 includes a third output 126-1 configured to deliver a third RF waveform to the electrode 128 and a fourth output 126-2 configured to deliver a fourth RF waveform to the electrode 128. In other embodiments, the bias RF generator 126 includes a third generator having the third output 126-1 configured to deliver the third RF waveform to the electrode 128 and a fourth generator having the fourth output 126-2 configured to deliver the fourth RF waveform to the electrode 128. In various embodiments, the third RF waveform has a third power level, a third frequency, and a third impedance. In one or more embodiments, the fourth RF waveform has a fourth power level, a fourth frequency, and a fourth impedance. In certain embodiments, the third impedance includes a third real component and a third imaginary component, and the fourth impedance includes a fourth real component and a fourth imaginary component.

In one or more embodiments, the electrode 128 (which represents a load based on the plasma 104 when the bias RF generator is a source of RF power transfer) has a corresponding impedance which may change over time. In order to maximize power transfer from the third output 126-1 to the electrode 128, the third impedance of the third RF waveform should be tuned to match the impedance of the electrode 128 (e.g., the load based on the plasma 104). Similarly, in order to maximize power transfer from the fourth output 126-2 to the electrode 128, the fourth impedance of the fourth RF waveform should be tuned match the impedance of the electrode 128 (e.g., the load based on the plasma 104).

In some embodiments, in order to tune the third and fourth impedances of the third and fourth RF waveforms to match the impedance of the electrode 128 (e.g., the load based on the plasma 104), an RF match system 132 is disposed between the bias RF generator 126 (e.g., the third output 126-1 and the fourth output 126-2) and a junction-box 134. In one or more embodiments, the RF match system 132 is an electrical circuit disposed between the third and fourth outputs 126-1, 126-2 and the electrode 128 for optimizing efficiency of power delivery to the load based on the plasma 104 through the electrode 128. In certain embodiments, the RF match system 132 is configured to match the third and fourth impedances of the third and fourth RF waveforms with the impedance of the load based on the plasma 104 through the electrode 128 as described in greater detail with respect to FIGS. 1B and 1C.

The junction-box 134 is configured to control or manage operations of components/subsystems within the plasma processing system 100. For example, the junction-box 134 can supply power to different components of the plasma processing system 100 (e.g., the chucking electrode 124, the bias RF generator 126, etc.) and/or facilitate transmission of control signals or data between the different components of the plasma processing system 100. The junction-box 134 is electrically and/or communicatively coupled to the chucking electrode 124, the bias RF generator 126, a high voltage DC supply 136, and a waveform generator 138.

The high voltage DC supply 136 includes a voltage source capable of outputting example voltages of +/−750 V, +/−1500 V, +/−3000 V, etc. In some embodiments, the waveform generator 138 generates a pulsed waveform, and the junction-box 134 controls an integration of the waveform generator 138 and the high voltage DC supply 136 to deliver a pulsed voltage (PV) waveform from a voltage source (e.g., the waveform generator 138 and the high voltage DC supply 136) to the chucking electrode 124. In some embodiments, the waveform generator 138 and the high voltage DC supply 136 are electrically coupled to the chucking electrode 124 via the junction-box 134. The bias RF generator 126 and the RF match system 132 can be electrically coupled to the electrode 128 via the junction-box 134.

The plasma processing system 100 is illustrated to include a controller 140 which includes a computing device having one or more processors, memory, and storage. The one or more processors can include central processing units, graphics processing units, accelerators, etc. The memory includes main memory for storing instructions for the one or more processors to execute or data for the one or more processors to operate on. For example, the memory includes random access memory (RAM). The storage includes mass storage for data or instructions. As an example and not by way of limitation, the storage may include a removable disk drive, flash memory, an optical disc, a magneto-optical disc, magnetic tape, or a Universal Serial Bus drive or two or more of these. The storage may include removable or fixed media and may be internal or external to the computing device. The storage may include any suitable form of non-volatile, solid-state memory, or read-only memory. The controller 140 includes a non-transitory computer readable medium or media. The non-transitory computer readable medium or media may include one or more semiconductor-based or other integrated circuits (ICs) (such, as for example, field-programmable gate arrays or application-specific ICs), hard disk drives, hybrid hard drives, optical discs, optical disc drives, magneto-optical discs, magneto-optical drives, solid-state drives, RAM drives, any other suitable non-transitory computer readable storage medium/media, or any suitable combination. The non-transitory computer readable medium or media may be volatile, non-volatile, or a combination of volatile and non-volatile. The controller 140 can be communicatively/electrically coupled to the source RF generator 120, the bias RF generator 126, the waveform generator 138, and/or the junction-box 134.

FIG. 1B is a schematic representation of an example radio frequency (RF) match system 142. In some embodiments, the RF match system 142 is representative of the RF match system 122 and the RF match system 132. The RF match system 142 is illustrated as receiving a first input 142-1 and a second input 142-2. In an example in which the RF match system 142 is representative of the RF match system 122, the first output 120-1 corresponds to the first input 142-1 and the second output 120-2 corresponds to the second input 142-2. In another example in which the RF match system 142 is representative of the RF match system 132, the third output 126-1 corresponds to the first input 142-1 and the fourth output 126-2 corresponds to the second input 142-2.

As shown, the RF match system 142 includes a sensor 144 for the first input 142-1, a sensor 146 for the second input 142-2, and a tuning circuit 148. The tuning circuit 148 is described in greater detail with respect to FIG. 1C. The RF match system 142 is illustrated to include a controller 150, an interlock 152, a memory 154, a filter 156, and a sensor 158 for an output of the RF match system 142. The controller 150 includes a computing device having one or more processors, memory (e.g., the memory 154), and storage. The one or more processors can include central processing units, graphics processing units, accelerators, etc. The memory (e.g., the memory 154) includes main memory for storing instructions for the one or more processors to execute or data for the one or more processors to operate on.

In some embodiments, the interlock 152 is configured to ensure that at least one condition is met before supplying RF power to the processing region 106 of the plasma processing chamber 102. In various examples, the at least one condition may be a check on cooling systems, gas flow rates, vacuum levels, etc. In one or more embodiments, the interlock 152 may be configured to implement an emergency shutdown of a portion of the plasma processing system 100 in response to detecting a fault associated with the portion of the plasma processing system 100.

In one or more embodiments, the waveform generator 138 outputs a transistor-transistor logic (TTL) synchronization signal which is received at the RF match system 142 via the controller 140 (e.g., FIG. 1A). In various embodiments, the RF match system 142 uses the TTL synchronization signal to synchronize the first input 142-1 and the second input 142-2 and also to synchronize the sensor 144 for the first input 142-1, the sensor 146 for the second input 142-2, and the sensor 158 for the output of the RF match system 142. In some embodiments, the RF match system 142 uses a multilevel pulsing synchronization signal or an external pulsing synchronization signal to synchronize the first input 142-1 and the second input 142-2 and also to synchronize the sensor 144 for the first input 142-1, the sensor 146 for the second input 142-2, and the sensor 158 for the output of the RF match system 142.

In some embodiments, the one or more processors of the controller 150 execute instructions which cause the one or more processors to adjust capacitances of variable capacitors included in the tuning circuit 148 to match an impedance of the first input 142-1 with an impedance of a load at a first time and also to match an impedance of the second input 142-2 with an impedance of the load at a second time. In a first example in which the RF match system 142 is representative of the RF match system 122, the instructions executed by the one or more processors of the controller 150 cause the one or more processors to adjust capacitances of the variable capacitors included in the tuning circuit 148 to match the first impedance of the first RF waveform with an impedance of the plasma 104 at a first time and to match the second impedance of the second RF waveform with an impedance of the plasma 104 at a second time. In the first example, the tuning circuit 148 outputs either the first RF waveform or the second RF waveform at different times. For example, the tuning circuit 148 may output the first RF waveform during a first portion of a cycle and the tuning circuit 148 may output the second RF waveform during a second portion of the cycle, wherein, in one example, the cycle relates to a separate voltage waveform provided to the plasma 104 by the waveform generator 138.

In a second example in which the RF match system 142 is representative of the RF match system 132, the instructions executed by the one or more processors of the controller 150 cause the one or more processors to adjust capacitances of the variable capacitors included in the tuning circuit 148 to match the third impedance of the third RF waveform with an impedance of the electrode 128 (e.g., based on the plasma 104 at a third time) and to match the fourth impedance of the fourth RF waveform with an impedance of the electrode 128 (e.g., based on the plasma 104 at a fourth time). In the second example, the tuning circuit 148 outputs either the third RF waveform or the fourth RF waveform at different times. In some examples, the tuning circuit 148 may output the third RF waveform during a first portion of a cycle and the tuning circuit 148 may output the fourth RF waveform during a second portion of the cycle.

### Impedance Tuning Examples

FIG. 1C is a schematic representation of an example tuning circuit 148. The tuning circuit 148 is illustrated to include a first input 160 and a second input 162. Although the illustrated example includes two inputs, it is to be appreciated that, in other embodiments, the tuning circuit 148 may include three inputs, four inputs, five inputs, more than five inputs, etc. A first variable shunt capacitor 164 is electrically connected to the first input 160 and a second variable shunt capacitor 166 is electrically connected to the second input 162. Notably, in an example of the tuning circuit 148 having three inputs, a third variable shunt capacitor is electrically connected to a third input.

In some embodiments, additional circuitry 168 is included in a first electrical path from the first input 160 to a third variable capacitor 170 and additional circuitry 169 is included in a second electrical path from the second input 162 to the third variable capacitor 170. In certain embodiments, the additional circuitries 168, 169 may be utilized to isolate (reduce crosstalk, interference, and/or distortion between) the first and second inputs 160, 162, respectively, and/or to improve impedance matching (e.g., for imaginary impedance components). In various embodiments, a capacitance of the first variable shunt capacitor 164 is adjustable to match a real component of an impedance of the first input 160 with a first real component of an impedance of a load (e.g., the plasma 104, the electrode 128, etc.). In one or more embodiments, a capacitance of the second variable shunt capacitor 166 is adjustable to match a real component of an impedance of the second input 162 with a second real component of the impedance of the load.

In various embodiments, the frequency of the first input 160 and the frequency of the second input 162 may be in a range of 100 kHz to 200 MHz. In certain embodiments, a capacitance of the third variable capacitor 170 is adjustable to match an imaginary component of the impedance of the first input 160 with a first imaginary component of the impedance of the load. In various embodiments, the capacitance of the third variable capacitor 170 is adjustable to match an imaginary component of the impedance of the second input 162 with a second imaginary component of the impedance of the load. In some embodiments, the first variable shunt capacitor 164, the second variable shunt capacitor 166, and the third variable capacitor 170 may have adjustable capacitance values in a range of 3 pF to 2000 pF.

In an example in which the RF match system 142 is representative of the RF match system 122, the one or more processors of the controller 150 execute instructions that cause the one or more processors to adjust the capacitance of the first variable shunt capacitor 164; adjust the capacitance of the third variable capacitor 170; and adjust the first frequency of the first RF waveform based on the impedance of the first RF waveform for minimum reflected power. In this example, the instructions executed by the one or more processors of the controller 150 cause the one or more processors to adjust the capacitance of the second variable shunt capacitor 166; adjust the capacitance of the third variable capacitor 170; and adjust the second frequency of the second RF waveform based on the impedance of the second RF waveform for minimum reflected power. Continuing this example, the one or more processors iteratively adjust the capacitance of the first variable shunt capacitor 164; adjust the capacitance of the third variable capacitor 170; and adjust the first frequency of the first RF waveform based on the impedance of the first RF waveform for minimum reflected power at a first time, and then adjust the capacitance of the second variable shunt capacitor 166; adjust the capacitance of the third variable capacitor 170; and adjust the second frequency of the second RF waveform based on the impedance of the second RF waveform for minimum reflected power at a second time until minimum reflected power is achieved at both states and instances in time. During this process, in some embodiments, the TTL synchronization signal triggers and controls the delivery of the first RF waveform and the second RF waveform. Upon achieving the minimum reflected power at both states, the adjusted capacitances of the first variable shunt capacitor 164, the second variable shunt capacitor 166, and the third variable capacitor 170 are held fixed, and the RF match system 142 is capable of tuning to multiple varying impedances within a short timescale (e.g., about a microsecond) for matching the impedances of the plasma 104. In various embodiments, the first RF waveform having the matched first impedance is delivered to an output 172 or the second RF waveform having the matched second impedance is delivered to the output 172. In some embodiments, the output 172 is passed through the filter 156, measured by the sensor 158 for the output of the RF match system 142, and delivered to the processing region 106 of the plasma processing chamber 102.

In an example in which the RF match system 142 is representative of the RF match system 132, the one or more processors of the controller 150 execute instructions that cause the one or more processors to adjust the capacitance of the first variable shunt capacitor 164; adjust the capacitance of the second variable shunt capacitor 166; adjust the capacitance of the third variable capacitor 170; adjust the third frequency of the third RF waveform based on the impedance of the third RF waveform; and adjust the fourth frequency of the fourth RF waveform based on the impedance of the fourth RF waveform in a same or similar manner as described with respect to the RF match system 122 above. Upon achieving the minimum reflected power at both states at each different time, the adjusted capacitances of the first variable shunt capacitor 164, the second variable shunt capacitor 166, and the third variable capacitor 170 are held fixed, and the RF match system 142 is capable of tuning to multiple varying impedances within a short timescale (e.g., about a microsecond) for matching the impedance of the electrode 128 (e.g., based on the plasma 104). In one or more embodiments, the third RF waveform having the matched third impedance is delivered to the output 172 or the fourth RF waveform having the matched fourth impedance is delivered to the output 172. In various embodiments, the output 172 is passed through the filter 156, measured by the sensor 158 for the output of the RF match system 142, and delivered to the processing region 106 of the plasma processing chamber 102.

FIG. 1D illustrates a graph 190 of a typical voltage waveform established at a substrate disposed on the substrate support 130 of the substrate support assembly 108 of the plasma processing system 100 due to the delivery of PV waveforms to the chucking electrode 124 of the plasma processing system 100 by the waveform generator 138. A first waveform (e.g., a PV waveform 195) is an example of a non-compensated PV waveform established at the substrate during plasma processing which will cause an impedance of the plasma 104 to vary over time. The PV waveform cycle of the waveform 195 has a period Tₚ, which is, for example, typically between 2 microsecond (μs) and 10 μs, such as 2.5 μs. The ion current stage of the PV waveform cycle will typically take up between about 50% and about 95% of the period Tₚ, such as from about 80% to about 90% of the period Tₚ.

The PV waveform 195 includes two main stages: an ion current stage and a sheath collapse stage. Both portions (e.g., the ion current stage and the sheath collapse stage) of the waveforms 195, can be alternately and/or separately established at the substrate during the plasma processing. At a beginning of the ion current stage, a drop in the voltage at the substrate is created, due to the delivery of a negative portion of the PV waveform (e.g., the ion current portion) provided to the chucking electrode 124 by the waveform generator 138, which generates a high voltage sheath above the substrate. The high voltage sheath allows the plasma generated positive ions to be accelerated towards the biased substrate during the ion current stage, and thus, for RIE processes, controls the amount and characteristics of the etching process that occurs on the surface of the substrate during the plasma processing. The sheath collapse stage includes a positive voltage swing (e.g., as a result of the positive wafer voltage), and the ion current stage includes a negative voltage swing (e.g., as a result of the positive wafer voltage), as illustrated in FIG. 1D.

A first impedance point 174 and a second impedance point 176 are depicted in the graph 190. As shown, the first impedance point 174 occurs at the start of the period Tₚ and the second impedance point 176 occurs at a start of or midpoint of the period Tₚ. In an example in which the period Tₚ is about 2.5 μs, conventional impedance matching systems are not capable of matching an impedance of a load at the first impedance point 174 and then matching an impedance of the load at the second impedance point 176 within an amount of time between the occurrence of the first impedance point 174 and the occurrence of the second impedance point 176. As a result, mismatched RF power delivered to the load by conventional systems at the second impedance point 176 is delivered inefficiently and may reflect back causing damage to the source RF generator 120 and/or the bias RF generator 126.

However, by using the tuning circuit 148 to match impedances of multiple RF waveforms, the described systems and techniques are capable of matching an impedance of a load at the first impedance point 174 and then matching an impedance of the load at the second impedance point 176 within the amount of time between the occurrence of the first impedance point 174 and the occurrence of the second impedance point 176. For instance, the RF match system 142 is capable of tuning to multiple impedances within a short timescale (e.g., about a microsecond). Because of this, matched RF power delivered to the load using the described systems and techniques is delivered efficiently and with minimum reflected power. This improvement corresponds to faster etching rates and better on wafer/substrate results.

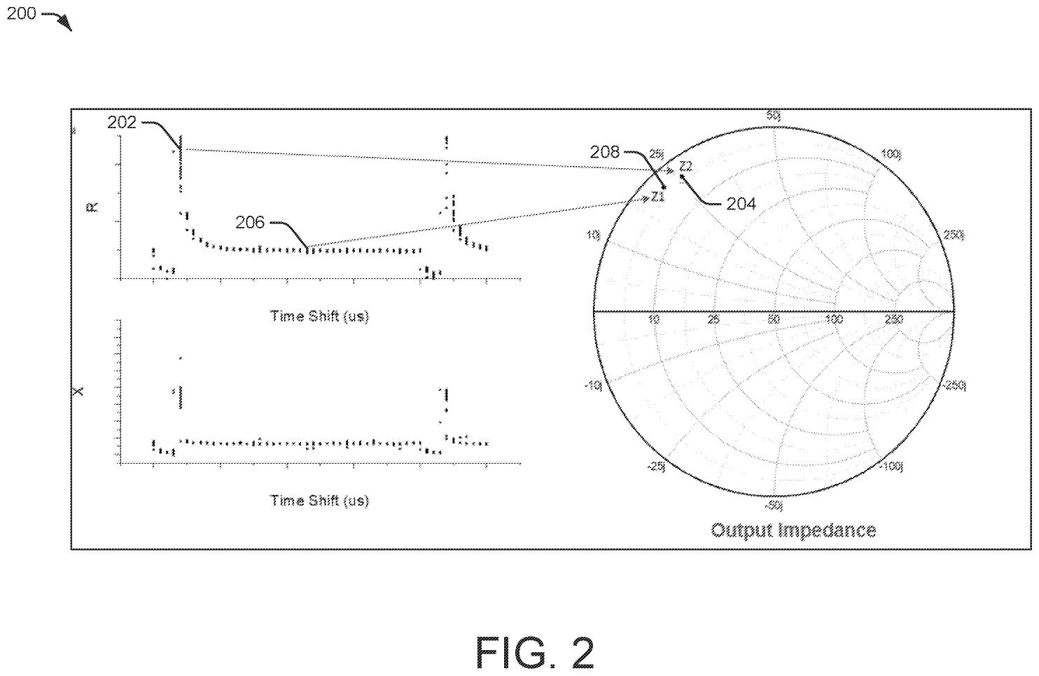

FIG. 2 illustrates a graph 200 of two example impedance states. As illustrated in FIG. 2, at a first point in time 202 an output impedance 204 has a real component value of about 17 units and an imaginary component value of about +25 j units. However, at a second point in time 206 which is only about 2 μs after the first point in time 202, an output impedance 208 has a real component value of about 12units and an imaginary component value of about +19 j units. Conventional systems are not capable of matching the output impedance 204 at the first point in time 202 and then matching the output impedance 208 at the second point in time 206. However, by using the tuning circuit 148 to match impedances of multiple RF waveforms, the described systems and techniques are capable of matching the output impedance 204 at the first point in time 202 and then matching the output impedance 208 at the second point in time 206.

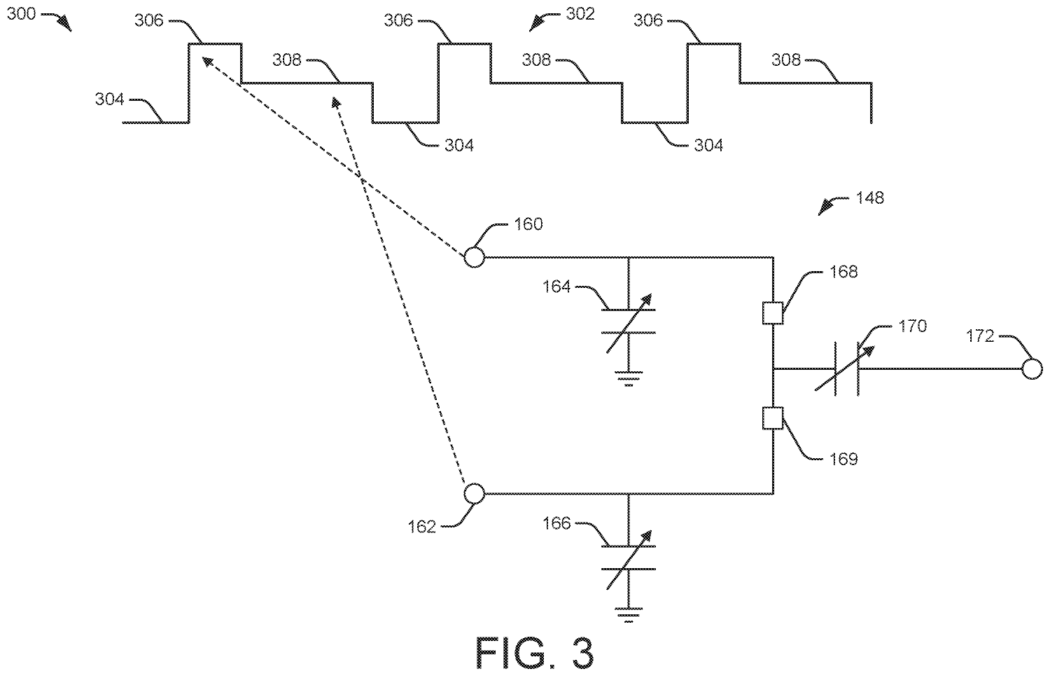

FIG. 3 illustrates a representation 300 of example radio frequency (RF) multilevel pulsing. As shown, the representation includes the tuning circuit 148 and a multilevel pulse RF waveform 302. The multilevel pulse RF waveform 302 includes a zero state 304 (e.g., an off state), a first state 306 (e.g., a first pulse state), and a second state 308 (e.g., a second pulse state). In some embodiments, the multilevel pulse RF waveform 302 is delivered to a load which can have a different impedance for the first state 306 than for the second state 308. However, the tuning circuit 148 is capable of matching the impedance of the load for the first state 306 by receiving the first state 306 as the first input 160. The tuning circuit 148 is also capable of matching the impedance of the load for the second state 308 by receiving the second state 308 as the second input 162. In one or more embodiments, the tuning circuit 148 matches the impedance of the load for the first state 306 in a same or similar manner as described above with respect to the first RF waveform and the RF match system 122, and the tuning circuit 148 matches the impedance of the load for the second state 308 in a same or similar manner as described above with respect to the second RF waveform and the RF match system 122.

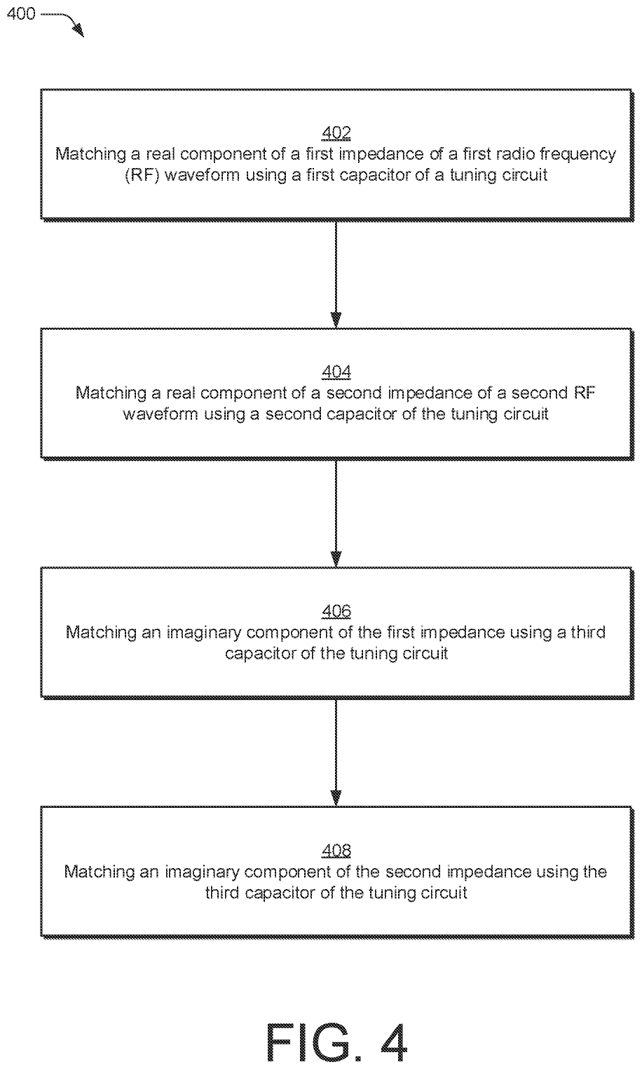

FIG. 4 is a flow diagram illustrating a method 400 of impedance tuning for plasma processing. At operation 402, a real component of a first impedance of a first radio frequency (RF) waveform is matched using a first capacitor of a tuning circuit. In some embodiments, the real component of the first impedance of the first RF waveform is matched with a real component of an impedance of the plasma 104 using the first variable shunt capacitor 164 of the tuning circuit 148.

At operation 404, a real component of a second impedance of a second RF waveform is matched using a second capacitor of the tuning circuit. In various embodiments, the real component of the second impedance of the second RF waveform is matched with a real component of an impedance of the plasma 104 using the second variable shunt capacitor 166 of the tuning circuit 148.

At operation 406, an imaginary component of the first impedance is matched using a third capacitor of the tuning circuit. In some embodiments, the imaginary component of the first impedance of the first RF waveform is matched with an imaginary component of an impedance of the plasma 104 using the third variable capacitor 170 of the tuning circuit 148.

At operation 408, an imaginary component of the second impedance is matched using the third capacitor of the tuning circuit. In certain embodiments, the imaginary component of the second impedance of the second RF waveform is matched with an imaginary component of an impedance of the plasma 104 using the third variable capacitor 170 of the tuning circuit 148.

### Additional Considerations

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or operations described with respect to one implementation may be combined with the features, components, and/or operations described with respect to other implementations of the present disclosure. As used herein, the term “about” may refer to a +/−10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more operations or actions for achieving the described method. The method operations and/or actions may be interchanged with one another without departing from the scope of the claims. In other words, unless a specific order of operations or actions is specified, the order and/or use of specific operations and/or actions may be modified without departing from the scope of the claims.

While the foregoing is directed to embodiments of the present disclosure, other and further embodiments of the disclosure may be devised without departing from the basic scope thereof, and the scope thereof is determined by the claims that follow.

We claim:

1. A method for plasma processing, comprising:
matching a real component of a first impedance of a first radio frequency (RF) waveform using a first capacitor of a tuning circuit;
matching a real component of a second impedance of a second RF waveform using a second capacitor of the tuning circuit;
matching an imaginary component of the first impedance using a third capacitor of the tuning circuit; and
matching an imaginary component of the second impedance using the third capacitor of the tuning circuit.

2. The method of claim 1, wherein the first RF waveform and the second RF waveform are output from an RF generator.

3. The method of claim 1, wherein the first RF waveform is output from a first RF generator and the second RF waveform is output from a second RF generator.

4. The method of claim 1, further comprising delivering the first RF waveform to a coil of a plasma processing system.

5. The method of claim 4, further comprising:
halting delivery of the first RF waveform to the coil; and
delivering the second RF waveform to the coil.

6. The method of claim 1, further comprising delivering the first RF waveform to an electrode of a plasma processing system.

7. The method of claim 6, further comprising:
halting delivery of the first RF waveform to the electrode; and
delivering the second RF waveform to the electrode.

8. The method of claim 1, further comprising tuning a frequency of at least one of the first RF waveform or the second RF waveform.

9. The method of claim 1, wherein the first RF waveform has a first frequency and the second RF waveform has a second frequency that is different from the first frequency.

10. The method of claim 1, wherein the first capacitor and the second capacitor are shunt capacitors.

11. The method of claim 10, wherein the tuning circuit includes a first electrical connection from the first capacitor to the third capacitor and a second electrical connection from the second capacitor to the third capacitor.

12. The method of claim 1, wherein the first RF waveform has a first power level and the second RF waveform has a second power level that is different from the first power level.

13. A tuning circuit, comprising:
a first capacitor coupled to an output of the tuning circuit and configured to match a real component of a first impedance of a first radio frequency (RF) waveform provided to a first input of the tuning circuit;
a second capacitor coupled to the output of the tuning circuit and configured to match a real component of a second impedance of a second RF waveform provided to a second input of the tuning circuit; and
a third capacitor coupled to the output of the tuning circuit and configured to match an imaginary component of the first impedance and match an imaginary component of the second impedance.

14. The tuning circuit of claim 13, further comprising additional circuitry configured to isolate the first RF waveform and the second RF waveform.

15. The tuning circuit of claim 13, wherein the first RF waveform, which is provided to the first input, and the second RF waveform, which is provided to the second input, are output from an RF generator.

16. The tuning circuit of claim 13, wherein the first RF waveform is output from a first RF generator to the first input, and the second RF waveform is output from a second RF generator to the second input.

17. The tuning circuit of claim 13, wherein the output of the tuning circuit is coupled to a coil of a plasma processing system.

18. The tuning circuit of claim 13, wherein the output of the tuning circuit is coupled to an electrode of a plasma processing system.

19. The tuning circuit of claim 13, wherein the first RF waveform has a first frequency and the second RF waveform has a second frequency that is different from the first frequency.

20. The tuning circuit of claim 19, wherein the first RF waveform has a first power level and the second RF waveform has a second power level that is different from the first power level.
